(19) United States
(12) Patent Application Publication
(10) Pub. No.: US 2015/0091032 A1
(43) Pub. Date: Apr. 2, 2015

(54) Nickel-Titanium and Related Alloys as Silver Diffusion Barriers

(71) Applicant: Intermolecular, Inc., San Jose, CA (US)

(72) Inventors: Jianhua Hu, Palo Alto, CA (US); Minh Huu Le, San Jose, CA (US); Sandeep Nijhawan, Los Altos, CA (US); Teresa B. Sapirman, Mountain View, CA (US)

(73) Assignee: Intermolecular, Inc., San Jose, CA (US)

(21) Appl. No.: 14/136,196

(22) Filed: Dec. 20, 2013

Related U.S. Application Data
(60) Provisional application No. 61/884,282, filed on Sep. 30, 2013.

(51) Int. Cl. H01L 33/46

(52) U.S. Cl. CPC H01L 33/46
USPC 257/98; 438/29

(57) ABSTRACT

Diffusion of silver from LED reflector layers is blocked by 10-50 nm barrier layers of nickel-titanium (NiTi) alloys. Optionally, the alloys also include one or more of tungsten (W), niobium (Nb), aluminum (Al), vanadium (V), tantalum (Ta), or chromium (Cr). These barriers may omit the noble-metal (e.g., platinum or gold) cap used with silver barriers based on other materials.

### BACKGROUND

Related fields include light-emitting diodes (LEDs), laser diodes, and other optical, electronic, and optoelectronic devices based on III-V compound semiconductor materials (e.g., gallium nitride (GaN), aluminum nitride (AlN), indium nitride (InN), and ternary or quarternary nitrides and phosphides such as AlGaN, InGaN, GaInAsN, and GaInPN).

A typical LED stack includes an active semiconductor layer sandwiched between p-type and n-type semiconductor layers. Electroluminescence results when electrons from the n-type layer and “holes” from the p-type layer meet and combine in the active layer. Substrates made of III-V materials have historically been very expensive. GaN and AlN substrates are becoming increasingly available, but are still prone to problems related to stability and defects. A common alternative approach has been to grow the III-V layers by epitaxy on some other material such as sapphire (Al₂O₃), silicon (Si), silicon carbide (SiC), germanium (Ge), and zinc oxide (ZnO).

A “junction-up” LED emits light from the side opposite the substrate, through a semi-transparent contact. Some junction-up LEDs have one contact on the “top” (the side of the film stack farthest from the substrate) and one on the “bottom” (the side of the film stack nearest the substrate). An inverted (flip-chip or vertical chip) LED is fabricated to emit light toward the substrate. Depending on the design, the substrate may be removed before packaging, or may remain in place and become a transparent “superstrate.” A common challenge in designing electrical contacts for LEDs is that their optical properties are constrained along with their electrical properties. For the device to function, both current and light must be able to pass through the light-emitting stack.

Efficient light output in an LED can depend partially on the reflectivity of an internal reflector. Light radiating in some directions would ordinarily be absorbed by components behind or beside the light-emitting element, where it would be converted to waste heat and never reach the intended field of illumination. A reflector may be positioned inside the device to capture this light and redirect it toward the intended field of illumination. Some LED reflectors are made of conductive materials and also serve as electrodes or other electrical contacts. These dual-purpose components are referred to as “reflective contacts.”

Silver (Ag) is highly electrically conductive and also highly reflective over a broad range of optical wavelengths. It reflects visible wavelengths (˜400-650 nm) more efficiently than other readily available conductive metals such as aluminum, copper, and gold. However, several obstacles have hindered the cost-effective mass production of LEDs with internal silver reflectors.

Silver tends to diffuse into and through other material used in LED manufacturing. Diffusion degrades the reflectivity of the silver, and the composition changes or reactions induced by the diffused silver in other layers can compromise the performance of the finished device (for example, by increasing conductivity in a dielectric layer or forming scattering centers in a transparent layer).

Barrier layers have been developed using materials such as titanium-tungsten (TiW) alloy and non-diffusing noble metals such as platinum (Pt) or gold (Au). These materials are expensive. Additionally, these barrier layers are often 50-100 nm thick and may require an additional capping layer that is also on the order of 100 nm thick. Thicker layers increase production cost by using more material and consuming more process time.

Therefore, a need exists for an effective diffusion barrier for silver that is less costly than a thick barrier that includes Pt or Au. Such an improvement may be thinner, or use less-expensive materials, or both.

### SUMMARY

The following summary presents some concepts in a simplified form as an introduction to the detailed description that follows. It does not necessarily identify key or critical elements and is not intended to reflect a scope of invention.

Diffusion barriers based on nickel-titanium (NiTi) and related alloys effectively block silver diffusion, as shown by comparing reflectance measurements before and after heating the film stack. For example, after heating to 500 C for 20 minutes, the reflectance changes less than 5%, whereas a larger degradation would be expected if the Ag were diffusing through the barrier.

Some embodiments of the diffusion barriers have no Pt or Au content. In some embodiments, the weight percentage (wt %) of Ni in the diffusion barrier may be between about 50% and 95%. Related alloys used in some embodiments include NiTi with one or more of tungsten (W), niobium (Nb), aluminum (Al), vanadium (V), tantalum (Ta), or chromium (Cr). These materials are less expensive than Au and Pt. In some embodiments, the diffusion barrier remains amorphous after annealing (300-500 C depending on the material), providing no continuous grain boundaries for diffusing silver to penetrate. In some embodiments, the diffusion barrier crystallizes into a densely packed structure that is also difficult for Ag atoms to penetrate. Diffusion barrier thickness of 10-50 nm, significantly thinner than some prior diffusion barriers, have been shown to be are sufficient to block Ag diffusion.

Some embodiments of the diffusion barriers include multiple sub-layers: for example, a layer of pure Ti between two NiTi layers, or a layer of NiTiNb adjacent to the silver with a layer of pure Ti adjacent to the NiTiNb.

Some embodiments of the diffusion barriers may be made by physical vapor deposition (PVD), sputtering from a single target or from multiple targets. One or more targets may be pre-conditioned. One or more of the targets may be less than about 10% Ni by weight. The sputtering may be pulsed DC sputtering with 7000-9000 ns pulses separated by 1000-3000 ns pauses. Process conditions for the sputtering may be as follows: substrate temperature between 20 C and 30 C, power 2.5-20 W/cm², and pressure 2-10 mTorr. The sputtering may be done in the presence of argon (Ar) gas.

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIGS. 1A and 1B conceptually illustrate examples of LEDs.

FIGS. 2A and 2B conceptually illustrate the effect of a barrier layer.

FIG. 3 is a conceptual diagram of a PVD chamber.

FIG. 4 is a conceptual diagram of co-sputtering in an example PVD chamber.

FIGS. 5A-5D illustrate alternate placements for a barrier layer.

FIGS. 6A-6D illustrate examples of multi-layer barrier stacks.

FIG. 7 is a graph of experimental data comparing different barrier layers with and without Pt caps.

FIGS. 8A-8C are flowcharts of methods for forming barrier layers that include NiTi alloys.

FIG. 9 conceptually illustrates example LEDs with barrier-protected silver reflective contacts.

### DETAILED DESCRIPTION OF EXAMPLE EMBODIMENTS

Semiconductor manufacturing is generally a very complex process. Preceding and subsequent steps that do not necessarily affect the methods being described here, and techniques that are well known in the art, may be omitted to avoid excess length and confusion.

The arrangement of films and stacks within relevant devices may vary. While terms such as “above,” “below,” “over,” “under,” “top,” and “bottom” may be used herein for convenience in describing illustrated embodiments, inverted embodiments are also within the scope of invention. Similarly, some of the described processes, and subsets of steps within those processes, may be performed in reverse order to achieve the desired effect even though they may be described for convenience as “first,” “second,” etc. in the described examples.

Where a range of values is given for a parameter, all intervening values are included unless the text or context clearly dictates otherwise. “About” or “approximately” shall mean “within 10% of” unless otherwise specified. Singular articles “a,” “an,” and “the” (or the absence of an article) may encompass plural variations. For example, “a layer” may mean “one or more layers,” except where the text or context clearly indicates “only one layer.” “Or” in a list of multiple items means that any, all, or any combination of less than all the items in the list may be used.

As used herein, a “dopant” shall mean a deliberately added minor constituent (generally <20 atomic %) of a layer or material, and shall not encompass contaminants (e.g., carbon, trapped precursor ligands, etc.) that may be incidentally present. Dopants may or may not be electrically active. “Amorphous” shall mean “less than 30% crystalline as measured by X-ray diffraction,” and “crystalline” shall mean “30% crystalline or more as measured by X-ray diffraction.”

“Substrate” herein shall mean any workpiece on which layer formation or treatment is desired. Substrate materials may include, without limitation, silicon, silica, sapphire, zinc oxide, SiC, AlN, GaN, Spinel, coated silicon, silicon on oxide, silicon carbide on oxide, glass, gallium nitride, indium nitride, aluminum nitride, and combinations (or alloys) thereof. “Substrate” and “superstrate” may be used interchangeably herein.

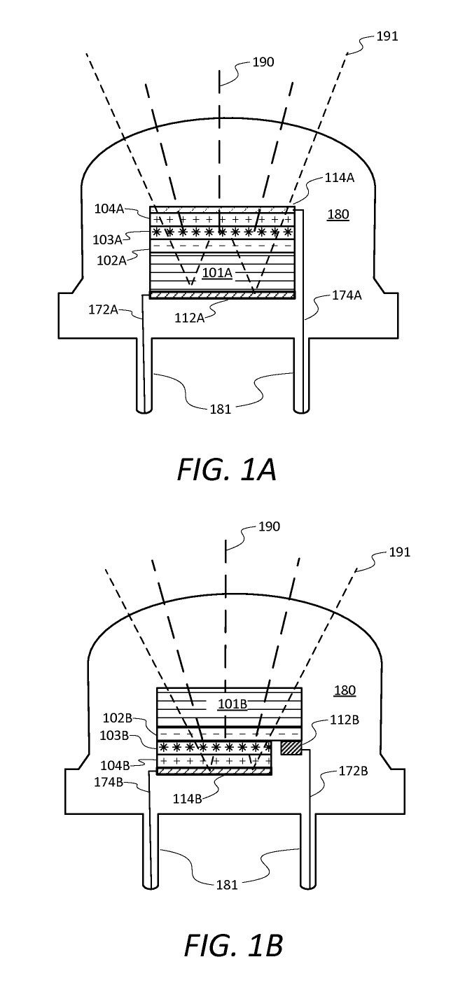

FIGS. 1A and 1B conceptually illustrate examples of LEDs. Many different LED designs exist, and new ones continue to be introduced. These examples are intended to provide basic context and do not limit the scope of application of the described reflective contacts.

FIG. 1A illustrates an example of a junction-up LED. Inside the transparent envelope of package 180, substrate 101A supports n-type semiconductor layer 102A, active photoemissive layer 103 A, and p-type semiconductor layer 104A (sometimes referred to as the “active stack”). Current delivered through terminal pins 181 is conducted through leads 172A and 174A to negative-polarity contact 112A and positive-polarity contact 114A. The current causes negative charge-carriers to migrate from n-type layer 102A into active photoemissive layer 103A, and positive charge-carriers to migrate from p-type layer 104A into active photoemissive layer 103A. When the negative charge-carriers and positive charge-carriers recombine in active photoemissive layer 103A, photons of light are emitted.

Upward-directed light 190 passes through positive-polarity contact 114A, illustrated here as a transparent electrode. In some LEDs, positive-polarity contact 114A is opaque or reflecting, but only covers part of the top surface so that light may emerge from the uncovered parts of the surface. Downward-directed light 191 passes through substrate 101A and is reflected from reflective negative-polarity contact 112A to redirect it upward, where it exits from the top surface.

In some junction-up LEDs, reflective negative-polarity contact 112A is between substrate 101A and n-type layer 102A. These designs do not require substrate 101A to be transparent; it may be an opaque material such as silicon carbide. In some junction-up LEDs, the positive-polarity components are underneath the active photoemissive layer and the negative-polarity components are above it.

FIG. 1B illustrates an example of a flip-chip LED. When this LED chip was fabricated, the film stack was formed on substrate 101B. When the die was installed in package 180, it was flipped upside-down to position substrate 101B on top (the former “substrate” became a “superstrate”). Part of the surface of the n-type semiconductor layer 102B is exposed to allow the attachment of negative-polarity contact 112B. In some LEDs, this removes the requirement that negative-polarity contact 112B have any particular optical properties. When current passes through the device from pins 181 through leads 172B and 174B, light is emitted from active photoemissive layer 103B. Light emitted from active photoemissive layer 103B toward superstrate 101B is transmitted directly out of the device. Light emitted from active photoemissive layer 103B toward P-type layer 104B is reflected from reflective positive-polarity contact 114B, which redirects it upward through superstrate 101B.

Both of these designs, and others, make use of reflective contacts. A high-performance, reliable reflective contact that is cost-effective to manufacture would advance the technology and benefit the industry.

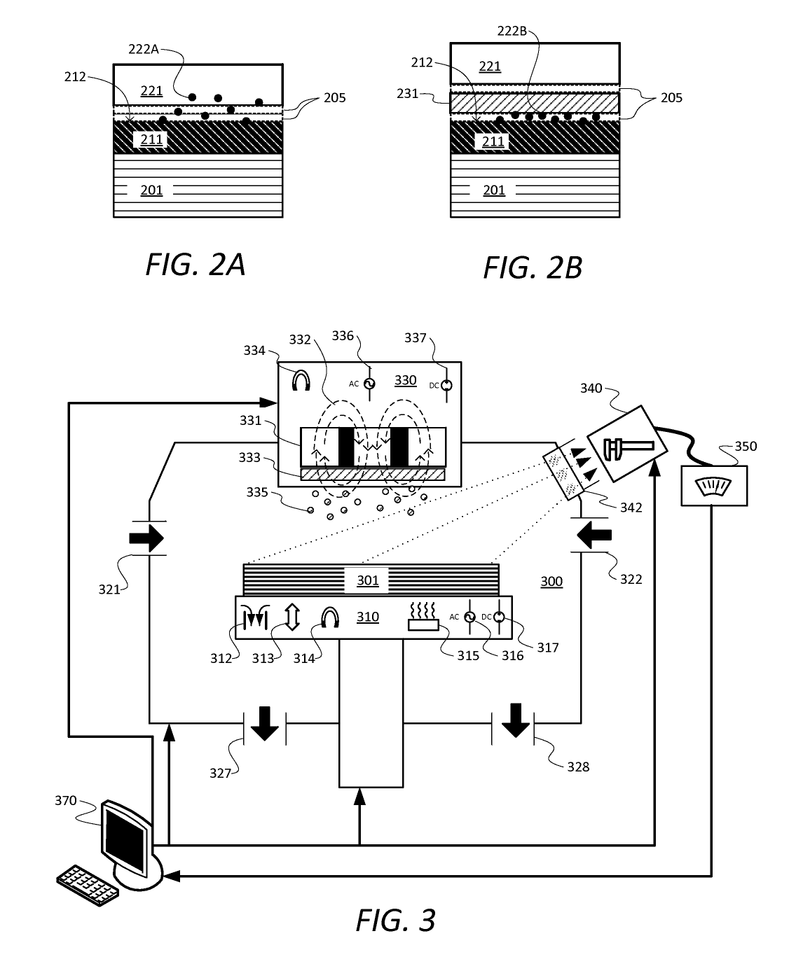

FIGS. 2A and 2B conceptually illustrate the effect of a barrier layer. In FIG. 2A, substrate 201 includes a silver layer 211 and a silver-sensitive layer 221. “Silver-sensitive layer,” as used herein, means a layer that would be impaired in its intended function (e.g., electrical insulation, optical transparency, emission of a desired spectrum of light) if it were to be contaminated by diffused silver. For example, consider a dielectric intended to insulate around a conductive electrode or interconnect. The dielectric would become more conductive (i.e., less insulating) if it contained diffused silver because silver is a conductive metal. Under some conditions, current could leak into or through the dielectric by tunneling between the diffused silver atoms, possibly causing a short circuit. As another example, a layer intended to be transparent, such as an anti-reflective layer, could become darkened or cloudy if it contained diffused silver because silver is not transparent. Additionally, any layer that would chemically react with diffused silver, resulting in a by-product that would compromise device performance, would be a silver-sensitive layer. These examples are not limiting; other types of silver-sensitive layers may be present in a device.

Intervening permeable layers 205 may be between silver layer 211 and silver-sensitive layer 221. Alternatively, there may be no intervening layers, in which case silver layer 211 and silver-sensitive layer 221 are in direct contact.

During a high-temperature anneal, or gradually over the life of the device, silver atoms 222A may diffuse out of silver layer 211. Even if intervening layers 205 are between silver layer 211 and silver-sensitive layer 221, the silver atoms 222A may pass through intervening layers 205 into silver-sensitive layer 221 if the intervening layers 205 are silver-permeable. Meanwhile, the diffusion (and any accompanying chemical reactions with neighboring layer materials) degrades the specular reflectivity of silver reflective surface 212.

In FIG. 2B, a barrier layer 231 is interposed between silver-sensitive material 221 and silver layer 211. Barrier layer 231 is sufficiently conductive that it does not interfere with the passage of current through the stack. Barrier layer 231 may also be optically transparent at a wavelength range of interest, such as that of the LED's light-emitting element. The material for barrier layer 231 is selected to resist diffusion of silver atoms 222B. For example, it may be an amorphous material or a dense crystalline material, offering no grain boundaries or other convenient migration paths for diffusing silver atoms. Thus silver-sensitive material atoms 222B can only diffuse as far as barrier layer 231; they cannot reach silver-sensitive layer 211. Intervening layers 205 may be formed between barrier layer 231 and either silver layer 211 or silver-sensitive layer 221. Alternatively, barrier layer 231 may be in direct contact with silver layer 211, silver-sensitive material layer 221, or both. Although barrier layer 231 is illustrated as a single layer in this figure, multi-layer barrier stacks are also contemplated.

Embodiments of barrier layers comprising various NiTi alloys, with or without additional metals (W, Al, Nb, Cr, V, Ta), sputtered by pulsed DC PVD to 10-50 nm thicknesses according to methods described herein, have been experimentally shown to satisfy the desired criteria of conductivity, transparency, and diffusion resistance for silver. These NiTi-based alloys have wide process windows (that is, they are tolerant to wide ranges of process conditions) and are compatible with a wide variety of other materials used in LED manufacturing.

FIG. 3 is a conceptual diagram of a PVD chamber. Chamber 300 includes a substrate holder 310 for holding a substrate 301. Substrate holder 310 may include a vacuum chuck 312, translation or rotational motion actuators 313, a magnetic field generator 314, a temperature controller 315, and circuits for applying an AC voltage bias 316 or DC voltage bias 317 to substrate 301. Some chambers include masks (not shown) for exposing only part of substrate 301 to the PVD process. The masks may be movable independent of the substrate. Chamber 300 includes inlets 321, 322 and exhausts 327, 328 for process gases. Process gases for PVD may include inert gases such as argon, and may also include reactive gases such as oxygen or nitrogen.

Chamber 300 includes at least one sputter gun 330 for sputtering elementary particles 335 (such as atoms or molecules) from a sputter target 333 by means of plasma excitation from the electromagnetic field generated by magnetron 331. Sputter gun 330 may include adjustments for magnetic field 334, AC electric field 336, or DC electric field 337. Some sputter guns 330 are equipped with mechanical shutters (not shown) to quickly start or stop the exposure of substrate 301 to elementary particles 335. Some PVD chambers have multiple sputter guns.

Some chambers 300 support measuring equipment 340 that can measure characteristics of the substrate 301 being processed through measurement ports 342. Results for measuring equipment 340 may be monitored by monitoring equipment 350 throughout the process, and the data sent to a controller 370, such as a computer. Controller 370 may also control functions of substrate holder 310, chamber 300 and its gas inlets and outlets 321, 322, 327, and 328, sputter gun 330, and measurement equipment 340.

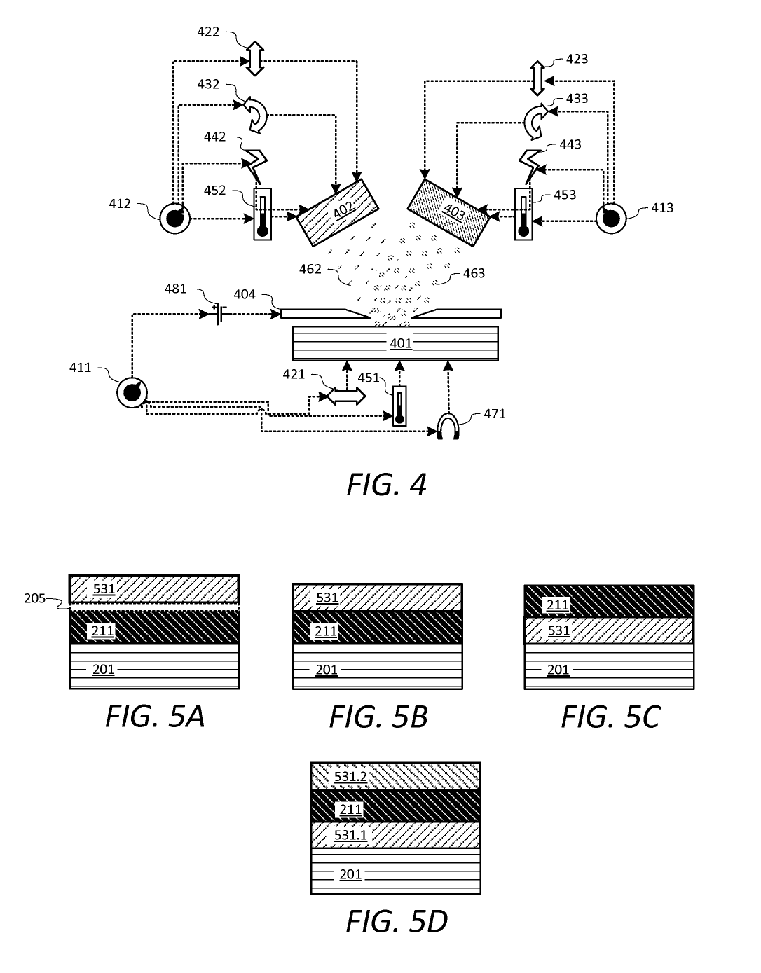

FIG. 4 is a conceptual diagram of co-sputtering in an example PVD chamber. Substrate 401 receives a first sputtered material 462 from a first target 402 and a second sputtered material 463 from a second target 403. A controller 412 may control one or more of position 422, angle 432, plasma power 442, and temperature 452 of target 402. A controller 413 may control one or more of position 423, angle 433, plasma power 443, and temperature 453 of target 403. Although the illustrated system shows two targets for simplicity, some embodiments may use more than two targets.

Controllers 412 and 413 for the separate targets may independently vary the respective targets' position, angle, plasma power, or temperature in real time as sputtering continues. Thus the separate targets can be sputtered at different plasma power levels or temperatures, or from different throw distances to the substrate, to vary the relative concentrations of each target material being deposited on the substrate. If at least one of the variables can be changed while sputtering continues, the composition of the film may be varied with depth if desired.

Some process chambers also have a controller 411 to vary the position 421, temperature 451, and local magnetic field 471 of substrate 401. Like the other controllers 412 and 413, controller 411 may be programmable, may be remote from the process chamber and operate via a wireless connection, and may be capable of varying the substrate's position, angle, plasma power, or temperature in real time as sputtering continues. “Position” in this block diagram is symbolized by a single two-headed arrow for simplicity, but it is intended to symbolize position variation in any or all directions. Some process chambers also have a mask 404 to block sputtered materials 462, 463 from reaching selected parts of substrate 401. Optionally, a controllable bias voltage 481 may be applied to mask 404. In process chambers equipped to change the relative position of substrate 401 and mask 404 during processing, different parts of substrate 401 may be sputtered with material having different proportions of first material 462 and second material 463.

FIGS. 5A-5D illustrate alternate placements for a barrier layer. In both figures, silver layer 211 is formed on substrate 201. Substrate 201 may also include multiple layers or structures formed beneath silver layer 211. In FIG. 5A, one or more intervening layers 205 are between silver layer 211 and barrier layer 531. In FIG. 5B, barrier layer 531 directly contacts silver layer 211. In FIG. 5C, barrier layer 531 is under silver layer 211 to protect silver-sensitive materials already on substrate 201. In FIG. 5D, a first barrier layer 531.1 is below silver layer 211 and a second barrier layer 531.2 is above silver layer 211. Barrier layers 531.1 and 531.2 may be, but are not necessarily, identical in composition, thickness, morphology, formation method, or some other characteristic. Materials for barrier layer 531 include, but are not limited to, NiTi alloys with or without added W, Nb, Al, Cr, V, or Ta. Ni content in the barrier layers may be between 50% and 95% by weight.

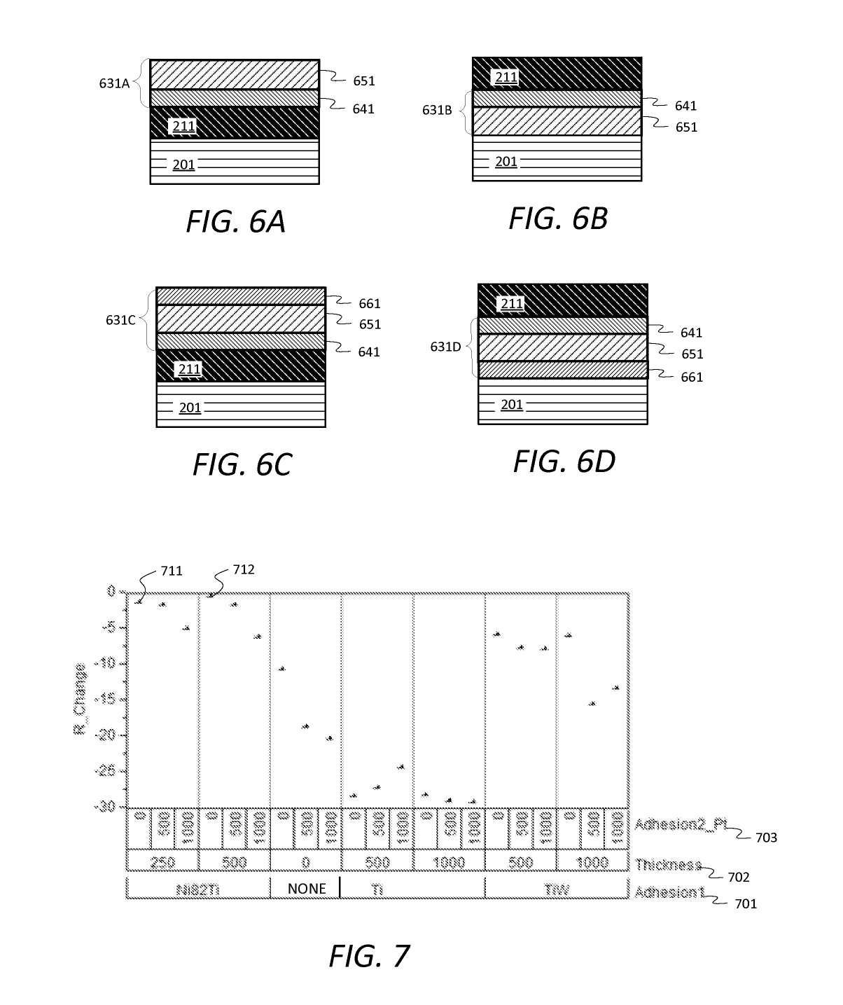

FIGS. 6A-6D illustrate examples of multi-layer barrier stacks. Barrier stacks 631A and 631B each include two sub-layers 641 and 651. Barrier stacks 631C and 631D each include three sub-layers 641, 651, and 661. As with the single barrier layers of FIGS. 5A and 5B, barrier stacks can be formed either under or over silver layer 211 on substrate 201. Sub-layers may be selected to provide adhesion, work-function matching, a specific type of electrical contact (e.g., ohmic or Schottky), or an optical interface (e.g., antireflective) with neighboring layers, as well as for barrier properties. For example, sub-layer 651 may be a NiTi alloy and sub-layer 641 may be a thin (e.g., <25 nm) noble-metal cap. Some embodiments of barrier stacks include no Au or Pt content and no Au or Pt layer in contact with the barrier. Alternatively, sub-layer 651 may be Ti and sub-layers 641, 661, or both may be a NiTi alloy. In some embodiments, the sub-layer contacting the silver is a NiTi alloy with or without added W, Nb, Al, Cr, V, or Ta.

Like single barrier layers, barrier stacks may be formed on either or both sides of the silver layer. Each layer may have a uniform composition, or at least one layer may have a composition gradient. The gradient may be produced by varying the power, position, or angle of one of the targets used for co-sputtering. Alternatively, the gradient may be produced when adjacent separate layers interdiffuse during annealing.

FIG. 7 is a graph of experimental data comparing different barrier layers with and without Pt caps. The Y-axis, R_change, is the change in reflectivity of a stack including silver and the barrier after heating to 500 C for 20 minutes. Diffusion of the silver causes a drop in reflectivity under these conditions. The less the reflectivity drops (the closer R_change is to zero), the less Ag has diffused; i.e., the more effectively the barrier works. The X-axis is divided into main sections by barrier material (row 701: NiTi alloy, no barrier layer (control), pure Ti, and TiW). Each main section is divided into subsections by the thickness of the barrier material in Ångstrom units (row 702: 1 Å=0.1 nm so that 250 Å=25 nm, 500 Å=50 nm, 1000 Å=100 nm; thickness with no barrier layer=0). Each subsection is divided into sub-subsections by the thickness of the Pt layer adjacent to the barrier (row 703: 0=no Pt, 500=500 Å=50 nm Pt, 1000=1000 Å=100 nm Pt). Data points 711 and 712, corresponding to NiTi barriers with no Pt, show the least reflectance degradation after heating (<2%), thus the best diffusion-blocking. The 50 nm NiTi layer (data point 712) lost slightly less reflectance than the 25 nm NiTi layer (data point 711) but both lost less than ¼ of the reflectance of any of the much thicker TiW barriers.

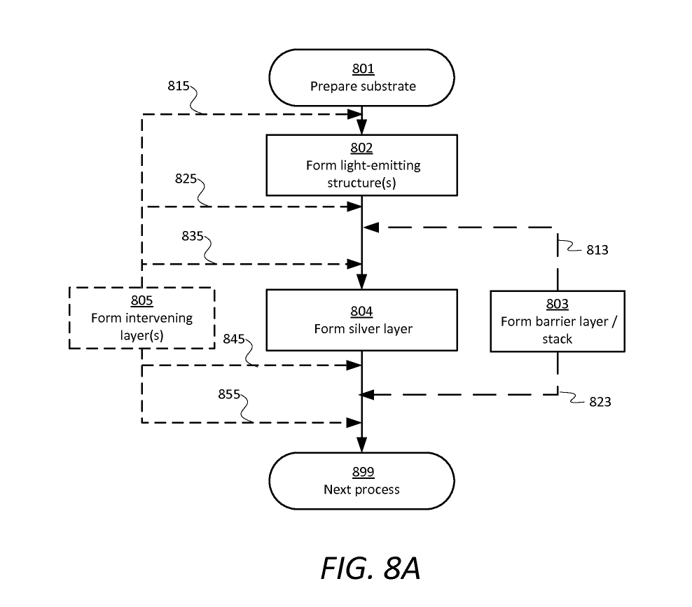

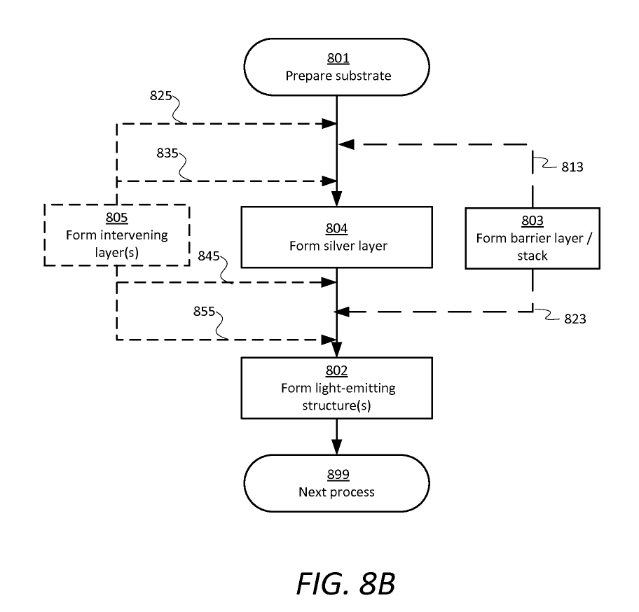

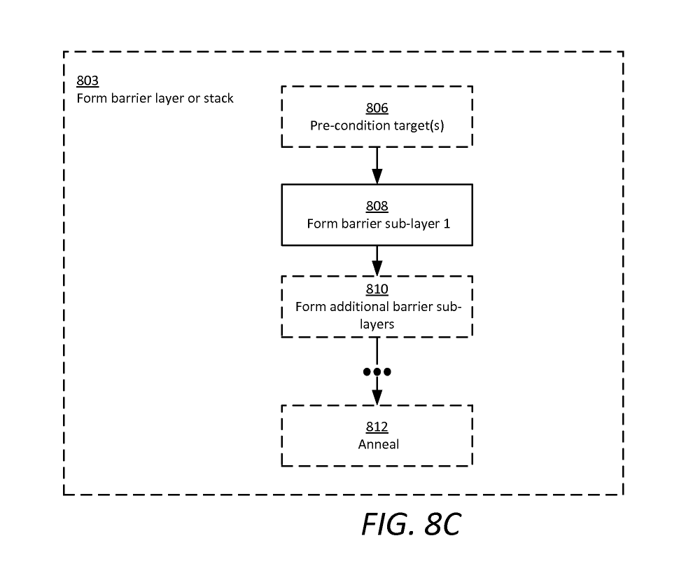

FIGS. 8A-8C are flowcharts of methods for forming barrier layers that include NiTi alloys. FIG. 8A is a flowchart of an example process where step 802 of forming the light-emitting layers (or other light-emitting structures) occurs after step 801 of preparing the substrate but before step 804 of forming the silver layer. Step 803 of forming the barrier layer may precede silver layer formation 804 (path 813), or follow silver layer formation 804 (path 823), or both (paths 813 and 823). Step 805 of forming any number of intervening layers may be done between substrate preparation 801 and light-emitting structure formation 802 (path 815), between light-emitting structure formation 802 and silver layer formation 804 (path 825 or 835), or after silver layer formation 804 (path 845 or 855). In some embodiments, the barrier layer or stack is in direct contact with the silver layer, without intervening layers between the barrier layer or stack and the silver layer.

FIG. 8B is a flowchart of an example process where the light-emitting structure formation 802 follows silver layer formation 804. Barrier layer formation 803 may precede silver layer formation 804 (path 813), or follow silver layer formation 804 (path 823), or both (paths 813 and 823 Formation 805 of any number of intervening layers may be done between substrate preparation 801 and silver layer formation 804 (path 825 or 835), or between silver layer formation 804 and light-emitting structure formation 802 (path 845 or 855). In some embodiments, the barrier layer or stack is in direct contact with the silver layer, without intervening layers between the barrier layer or stack and the silver layer.

In FIGS. 8A and 8B, barrier layer or stack formation 803 may include a PVD technique, such as a pulsed DC PVD technique that applies pulses of direct current to one or more sputtering targets. The pulses may have durations of 7000-9000 ns and may be separated by pauses of 1000-3000 ns. The power density applied at the target during the pulses may be 2.5-20 W/cm2. The pressure in the process chamber while sputtering may be 2-10 mTorr. Argon gas may be present in the chamber at a flow rate of 5-40 sccm. The substrate temperature may be between 20 C and 30 C.

Ni, Ti and any added metals such as W, Al, Nb, Cr, V, or Ta may all be present in a single target, or they may be co-sputtered from multiple separate targets. At least one of the targets may have less than about 10% Ni content (e.g., between 0.1% and 10% Ni). In some embodiments, a target may have greater Ni content and a magnetic field may be generated at the substrate to assist in the Ni sputtering. The co-sputtering may apply different power densities, positions, orientations, temperatures, or lengths and timings of the DC pulses to the separate targets. The power, duty cycle, or other characteristic of the electromagnetic field applied to a target may be varied during the co-sputtering to produce a composition gradient in the barrier layer. Alternatively, the distance from a target to the substrate, or an angle between the target and the substrate, may be varied during the co-sputtering to produce the composition gradient.

FIG. 8C illustrates some example sub-operations that may be included in barrier layer formation 803. Optional step 806 of pre-conditioning one or more sputtering targets may include sputtering from one or more targets onto a dummy wafer for 10-20 minutes before introducing the substrate that will receive the barrier layer. Step 808 of forming a first barrier sub-layer may include, for example, pulsed DC sputtering or co-sputtering. In some embodiments, step 810 of forming additional barrier sub-layers follows first barrier sub-layer formation 808. An annealing step 812 may follow at some point after all the barrier sub-layers are formed. Annealing 812 may be done directly after forming the barrier layer(s) or later in the LED fabrication process. Annealing temperatures may be between 300-600 C, depending on the materials of the barrier layer and the desired result of the annealing.

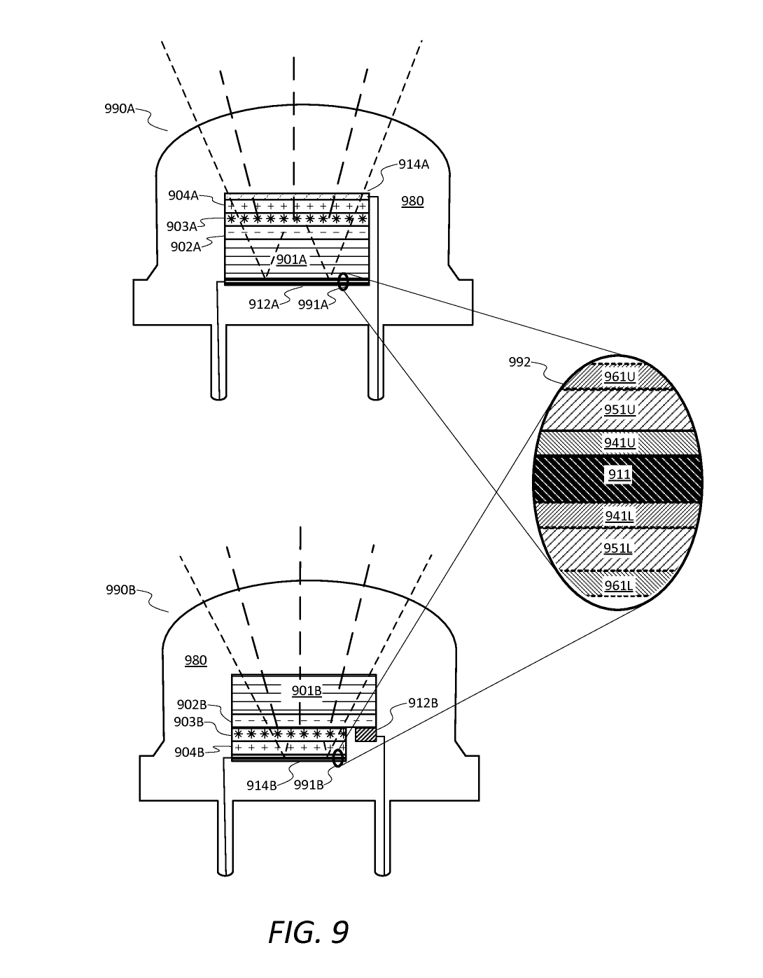

FIG. 9 conceptually illustrates example LEDs with barrier-protected silver reflective contacts. In junction-up LED 990A, the negative-polarity reflective contact 912A is barrier-protected silver. In flip-chip LED 990B, the positive-polarity reflective contact 912B is barrier-protected silver. Also shown are substrate 901A, n-type semiconductor layer 902A, active photoemissive layer 903A, p-type semiconductor layer 904A, and (transparent) positive-polarity contact 914A of junction-up LED 990A; and substrate 901B, n-type semiconductor layer 902B, active photoemissive layer 903B, p-type semiconductor layer 904B, and (partial-coverage) negative-polarity contact 912B of junction-up LED 990B.

To depict microscopic detail and macroscopic context in the same drawing, small areas (991A of reflective contact 912A, and 991B of reflective contact 914B) are magnified in magnification view 992. At a minimum, each of the reflective contacts has a silver layer 911 and an upper NiTi-based barrier layer 941U. To clarify, the upper “U” layers are between silver layer 911 and substrate 101A in LED 990A, and they are between silver layer 911 and p-type semiconductor layer 904B in LED 990A. Optionally, the reflective contacts may have multi-layer upper barrier stacks: 941U and 951U, or 941U, 951U, and 961U. Any barrier layer configuration described with respect to FIG. 5A-5D or 6A-6D, or any combination or equivalent, may be used above the silver layer.

Optionally, one or more barrier layers 941L and/or 951L and/or 961L may be used below silver layer 911 to protect silver layer 911 from any unwanted interactions with materials in the LED packaging, soldering of the leads, or those used in any other process. Any barrier layer configuration described with respect to FIG. 5A-5D or 6A-6D, or any combination or equivalent, may be used below the silver layer. Where barriers are used both above and below the silver layer, the layers or stacks may or may not be alike.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A light-emitting device, comprising:
a substrate;
a light-emitting structure on the substrate;
a silver layer operable to reflect emitted light from the light-emitting element; and
an alloy layer between the silver layer and a silver-sensitive layer;
wherein the alloy layer comprises nickel and titanium;
wherein the alloy layer is between about 10 nm and 50 nm thick; and
wherein a reflectance of the silver layer at a wavelength of the emitted light changes less than 5% after heating to 500 C for 20 minutes.

2. The light-emitting device of claim 1, wherein the alloy layer also comprises at least one of tungsten, niobium, aluminum, vanadium, tantalum, or chromium.

3. The light-emitting device of claim 2, wherein the alloy layer comprises at least two sub-layers; wherein the alloy layer comprises niobium; and wherein the niobium in the alloy layer is confined to the sub-layer nearest to the silver layer.

4. The light-emitting device of claim 1, wherein the alloy layer comprises nickel between 50% and 90%.

5. The light-emitting device of claim 1, wherein the alloy layer is devoid of platinum or gold.

6. The light-emitting device of claim 1, wherein no layer comprising platinum or gold is in contact with the alloy layer.

7. The light-emitting device of claim 1, wherein the alloy layer is amorphous.

8. The light-emitting device of claim 1, wherein the alloy layer is crystalline.

9. The light-emitting device of claim 1, wherein the alloy layer comprises at least two sub-layers; and wherein the nickel in the alloy layer is confined to the sub-layer nearest to the silver layer.

10. The light-emitting device of claim 1, wherein the alloy layer comprises at least three sub-layers; and wherein the nickel in the alloy layer is confined to two outermost sub-layers.

11. A method of forming a light-emitting device, the method comprising:
forming a light-emitting structure;
forming a silver layer; and
forming an alloy layer by pulsed direct-current physical vapor deposition;
wherein the alloy layer comprises nickel and titanium;
wherein the alloy layer is in contact with the silver layer; and
wherein the alloy layer is between about 100 Å and 500 Å thick.

12. The method of claim 11, wherein the alloy layer is formed after the light-emitting structure.

13. The method of claim 11, wherein the alloy layer is formed before the light-emitting structure.

14. The method of claim 11, wherein the alloy layer is formed after the silver layer.

15. The method of claim 11, wherein the alloy layer is formed before the silver layer.

16. The method of claim 11, wherein the alloy layer is formed at a substrate temperature between 20 C and 30 C.

17. The method of claim 11, wherein a DC pulse of the direct-current physical vapor deposition has a duration of 7000-9000 ns; and wherein a pause after or before the DC pulse has a duration of 1000-3000 ns.

18. The method of claim 11, wherein the pulsed direct-current physical vapor deposition comprises co-sputtering from a plurality of targets.

19. The method of claim 11, wherein a power density applied to a target used for the physical vapor deposition is between 2.5 W/cm² and 20 W/cm².

20. The method of claim 11, wherein a target used for the physical vapor deposition comprises between 0.1% and 10% nickel by weight.
